(19) United States
(12) Patent Application Publication
(10) Pub. No.: US 2023/0130983 A1
(43) Pub. Date: Apr. 27, 2023

(54) SEMICONDUCTOR DEVICE, SEMICONDUCTOR PACKAGE, AND METHOD OF FABRICATING THE SEMICONDUCTOR PACKAGE

(71) Applicant: Samsung Electronics Co., Ltd., Suwon-si (KR)

(72) Inventors: Seyong Lee, Cheonan-si (KR); Jungseok Ahn, Seoul (KR); Kuyoung Kim, Seoul (KR)

(21) Appl. No.: 17/878,355

(22) Filed: Aug. 1, 2022

(30) Foreign Application Priority Data
Oct. 22, 2021 (KR) 10-2021-0141639

(51) Int. Cl. H01L 23/31; H01L 25/065; H01L 23/00; H01L 21/56

(52) U.S. Cl. CPC H01L 23/3135; H01L 25/0652; H01L 24/16; H01L 24/73; H01L 21/565; H01L 24/32; H01L 24/27; H01L 2924/1436; H01L 2924/1431; H01L 2224/2784; H01L 2924/1811; H01L 2924/1815; H01L 2924/182; H01L 2924/186; H01L 2224/16145; H01L 2224/16227; H01L 2224/16238; H01L 2224/32145; H01L 2224/32225; H01L 2224/3201; H01L 2224/32059; H01L 2224/32058; H01L 2224/73204; H01L 23/3675

(57) ABSTRACT

A semiconductor device includes: a plurality of semiconductor chips stacked on a substrate in a vertical direction; a filler structure including a plurality of horizontal underfill layers formed between adjacent semiconductor chips of the plurality of semiconductor chips and between the substrate and the stack of semiconductor chips, and including underfill sidewalls formed around the horizontal underfill layers and the plurality of semiconductor chips; and a molding resin surrounding the plurality of semiconductor chips at least on side surfaces of the plurality of semiconductor chips. The underfill sidewalls include a recess pattern, which is disposed on and along the side surfaces of at least one of the plurality of semiconductor chips, and is recessed in a direction parallel to an upper surface of the substrate at locations where the recess pattern meets the substrate.

### CROSS-REFERENCE TO RELATED APPLICATION

This application is based on and claims priority under 35 U.S.C. § 119 to Korean Patent Application No. 10-2021-0141639, filed on Oct. 22, 2021 in the Korean Intellectual Property Office, the disclosure of which is incorporated by reference herein in its entirety.

### BACKGROUND

The inventive concept relates to a semiconductor device, a semiconductor package, and a method of fabricating the semiconductor package, and more particularly, to a semiconductor device, which is less affected by the environment and peeling of components of which may be significantly reduced, a semiconductor package, and a method of fabricating the semiconductor package.

A non-conductive film (NCF) is frequently used as an underfill for packaging of semiconductor devices. However, as the size of a semiconductor device is reduced and the thickness thereof is reduced, various issues occur, and accordingly, there is a need for improvement with respect to exterior inspection and product reliability.

### SUMMARY

Aspects of the inventive concept provide a semiconductor device, which is less affected by the environment and peeling of components of which may be significantly reduced.

Aspects of the inventive concept also provide a semiconductor package, which is less affected by the environment and peeling of components of which may be significantly reduced.

Aspects of the inventive concept provide a method of fabricating a semiconductor package, which is less affected by the environment and peeling of components of which may be significantly reduced.

According to an aspect of the inventive concept, a semiconductor device includes: a plurality of semiconductor chips stacked on a substrate in a vertical direction; a filler structure including a plurality of horizontal underfill layers formed between adjacent semiconductor chips of the plurality of semiconductor chips and between the substrate and the stack of semiconductor chips, and including underfill sidewalls formed around the horizontal underfill layers and the plurality of semiconductor chips; and a molding resin surrounding the plurality of semiconductor chips at least on side surfaces of the plurality of semiconductor chips. The underfill sidewalls include a recess pattern, which is disposed on and along the side surfaces of at least one of the plurality of semiconductor chips, and is recessed in a direction parallel to an upper surface of the substrate at locations where the recess pattern meets the substrate.

According to another aspect of the inventive concept, a semiconductor package includes: a package substrate; an interposer substrate stacked on the package substrate; a first semiconductor device and a second semiconductor device arranged on the interposer substrate and spaced apart from each other in a lateral direction; and a molding resin surrounding side surfaces of both the first semiconductor device and the second semiconductor device. The first semiconductor device includes: a buffer chip; a plurality of memory devices stacked on the buffer chip and connected to each other via through-substrate vias (TSVs, which may be through-silicon vias); and an underfill fillet on side surfaces of the plurality of memory devices. In addition, the underfill fillet includes a recess pattern, which is disposed on and along the side surfaces of at least one of the plurality of semiconductor chips, and is recessed in a direction parallel to an upper surface of the buffer chip at locations where the recess pattern meets the buffer chip. In addition, the recess pattern includes a first surface facing the buffer chip and extending toward the plurality of semiconductor devices, and a second surface connecting the first surface to the upper surface of the buffer chip.

According to another aspect of the inventive concept, a semiconductor package includes: a package substrate; an interposer substrate stacked on the package substrate; a first semiconductor device and a second semiconductor device arranged on the interposer substrate to be spaced apart from each other in a lateral direction; and a molding resin surrounding side surfaces of both the first semiconductor device and the second semiconductor device. The first semiconductor device includes: a buffer chip; a plurality of memory devices stacked on the buffer chip and connected to each other via through-substrate vias (TSVs); and underfill sidewalls on side surfaces of the plurality of memory devices. In addition, the underfill sidewalls comprise an underfill fillet that includes a protrusion pattern, which is disposed on and along the side surfaces of the plurality of memory devices, and protrudes in a direction parallel to an upper surface of the buffer chip at locations where the protrusion pattern meets the buffer chip. In addition, the protrusion pattern includes a first surface, as a flat surface, in parallel with the buffer chip and extending in a direction away from the plurality of memory devices, and a second surface connecting the first surface to the upper surface of the buffer chip and including a flat surface substantially vertical with respect to the upper surface of the buffer chip.

According to another aspect of the inventive concept, a method of fabricating a semiconductor package includes: forming a dam structure, on a substrate, on a periphery of locations where a plurality of semiconductor devices are provided; providing the plurality of semiconductor devices on the substrate by using an adhesive material; curing the adhesive material so that an underfill fillet covers and protrudes from side surfaces of the plurality of semiconductor devices; partially removing the underfill fillet on the side surfaces of the plurality of semiconductor devices so that a thickness of the underfill fillet does not exceed a first thickness from the side surfaces; and forming a molding resin to surround the plurality of semiconductor devices in a lateral direction, wherein a distance between inner side surfaces of the dam structure and the side surfaces of the plurality of semiconductor devices is less than the first thickness.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an example embodiment;

FIG. 2 is a cross-sectional view of a first semiconductor device included in a semiconductor package, according to an example embodiment;

FIGS. 3A through 3C are partially enlarged views of region A1 in FIG. 2, according to example embodiments;

FIG. 4 is a cross-sectional view of a first semiconductor device included in a semiconductor package, according to another embodiment;

FIG. 5 is a partially enlarged view of region A2 in FIG. 4;

FIG. 6 is a cross-sectional view of a first semiconductor device included in a semiconductor package, according to another embodiment;

FIGS. 7A through 7C are partially enlarged views of region B1 in FIG. 6, according to example embodiments;

FIG. 8 is a cross-sectional view of a first semiconductor device included in a semiconductor package, according to another embodiment;

FIG. 9 is a partially enlarged view of region B2 in FIG. 8;

FIG. 10 is a flowchart of a method of fabricating a semiconductor package, according to an example embodiment;

FIGS. 11A through 11G are side views illustrating a method of fabricating a semiconductor package, according to example embodiments; and

FIGS. 12A through 12D are side views illustrating a method of fabricating a semiconductor package, according to example embodiments.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted.

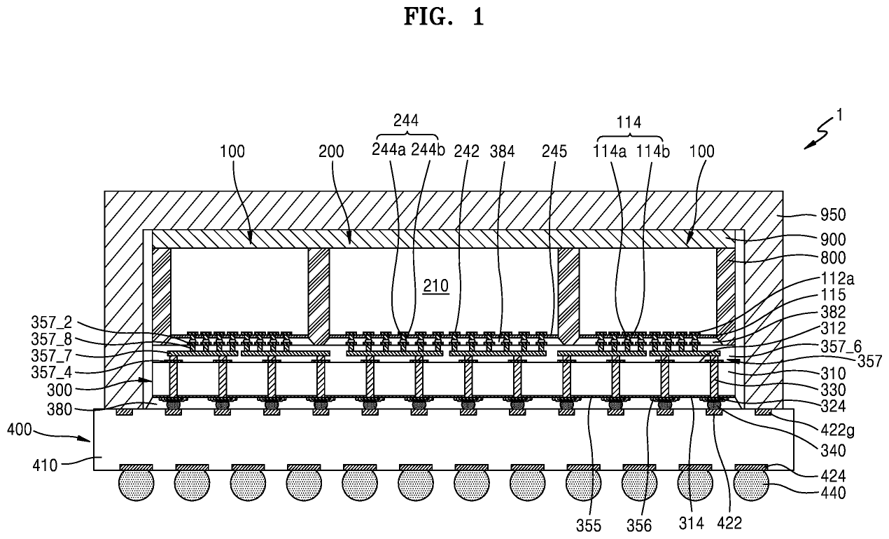

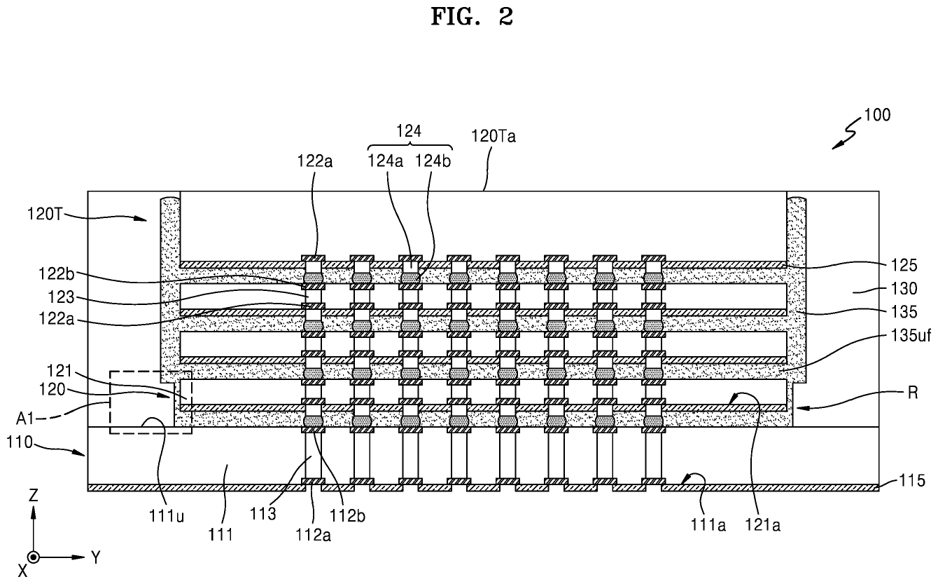

FIG. 1 is a cross-sectional view of a semiconductor package 1 according to an example embodiment. FIG. 2 is a cross-sectional view of a first semiconductor device 100 included in the semiconductor package 1, according to an example embodiment. A semiconductor device, as described herein, may refer to a semiconductor chip (e.g., an integrated circuit formed on a semiconductor die from a wafer), a stack of semiconductor chips, or a semiconductor package (e.g., one or more semiconductor chips formed on a package substrate; or a package-on-package structure).

Referring to FIGS. 1 and 2, the semiconductor package 1 may include a second substrate 400, over which a first substrate 300 is mounted, and the first semiconductor device 100 and a second semiconductor device 200, which are mounted on the first substrate 300. The first semiconductor device 100 and the second semiconductor device 200 may be mounted adjacent to each other in a horizontal direction on a redistribution structure 357 of the first substrate 300, to be spaced apart from each other in a lateral direction. In this case, the first semiconductor device 100 and the second semiconductor device 200 may be apart from each other in a lateral direction.

The first semiconductor device 100 and the second semiconductor device 200 may be electrically connected to the first substrate 300 via a plurality of first connection terminals 114 and a plurality of second connection terminals 244, respectively. The first semiconductor device 100 may include a plurality of first upper surface connection pads 112a, and the second semiconductor device 200 may include a plurality of second upper surface connection pads 242. The first substrate 300 may include a plurality of first redistribution pads 357_2. The plurality of first connection terminals 114 may be arranged between the plurality of first upper surface connection pads 112aand some of the plurality of first redistribution pads 357_2. The plurality of second connection terminals 244 may be arranged between the plurality of second upper surface connection pads 242 and the other of the plurality of first redistribution pads 357_2. The various pads and terminals described herein are formed of a conductive material, such as a metal, for example. More specific examples of the materials used form these pads and terminals will be described below.

Each of the plurality of first connection terminals 114 may include a first conductive pillar 114a on the first upper surface connection pad 112a and a first conductive cap 114b on the first conductive pillar 114a. Each of the plurality of second connection terminals 244 may include a second conductive pillar 244a on the second upper surface connection pad 242 and a second conductive cap 244b on the second conductive pillar 244a.

The first semiconductor device 100 may include a first semiconductor chip 110 and a plurality of second semiconductor chips 120. In FIG. 2, the first semiconductor device 100 is illustrated to include four second semiconductor chips 120, but is not limited thereto. For example, the first semiconductor device 100 may include two or more second semiconductor chips 120. In some embodiments, the first semiconductor device 100 may include the second semiconductor chips 120 of a multiple of four. The plurality of second semiconductor chips 120 may be sequentially stacked over the first semiconductor chip 110 in a vertical direction. Each of the first semiconductor chip 110 and the plurality of second semiconductor chips 120 may be sequentially stacked so that an active surface thereof faces downward (for example, toward the first substrate 300).

The first semiconductor chip 110 may include a first semiconductor substrate 111 including a first semiconductor element 111a formed on the active surface thereof, the first upper surface connection pad 112a and a first lower surface connection pad 112b respectively arranged on the active surface and an inactive surface of the first semiconductor substrate 111, a first through electrode 113 penetrating at least a portion of the first semiconductor substrate 111 and electrically connecting the first upper surface connection pad 112a to the first lower surface connection pad 112b, and a first protective insulating layer 115 exposing at least a portion of the first upper surface connection pad 112a and covering the active surface of the first semiconductor substrate 111. First upper surface connection pads 112a and first lower surface connection pads 112b, as well as other pads described herein, may generally be described as outer surface connection pads, as they are disposed at an outer surface of the first semiconductor substrate 111 and first semiconductor chip 110. Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures, and may refer to portions within a larger structure. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. Also, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first semiconductor substrate 111 may include or may be formed of, for example, a semiconductor material such as silicon (Si). Alternatively, the first semiconductor substrate 111 may include or be formed of a semiconductor element such as germanium (Ge), or a compound semiconductor such as silicon carbide (SiC), gallium arsenide (GaAs), indium arsenide (InAs), and indium phosphide (InP). The first semiconductor substrate 111 may include a conductive region, for example, a well doped with impurities. The first semiconductor substrate 111 may have various element isolation structures such as a shallow trench isolation (STI) structure.

In the inventive concept, an upper surface and a lower surface of a semiconductor substrate such as the first semiconductor substrate 111 may be referred to as an active surface side and an inactive surface side of the semiconductor substrate, respectively (or just an active surface and an inactive surface). For example, for naming purposes, even when the active surface of the semiconductor substrate is below the inactive surface of a final product, in the inventive concept, the active surface side of the semiconductor substrate may be referred to as the upper surface of the semiconductor substrate, and the inactive surface side of the semiconductor substrate may be referred to as the lower surface of the semiconductor substrate. In addition, the terms ‘an upper surface’ and ‘a lower surface’ may be used for components arranged on the active surface and for components arranged on the inactive surface of the semiconductor substrate, respectively.

The first semiconductor element 111a may be or may include one or more of various microelectronic elements, for example, a metal-oxide-semiconductor field effect transistor (MOSFET) such as a complementary metal-insulator-semiconductor (CMOS) transistor, an image sensor such as a system large scale integration (LSI) sensor, and a CMOS imaging sensor (CIS), a micro-electro-mechanical system (MEMS), an active element, a passive element, etc. The first semiconductor element 111a may be electrically connected to a conductive region of the first semiconductor substrate 111. In addition, the first semiconductor element 111a may be electrically separated from another first semiconductor element 111a adjacent thereto by an insulation layer.

In some embodiments, the first semiconductor chip 110 may be or may include, for example, a dynamic random-access memory (RAM) (DRAM) chip, a static RAM (SRAM) chip, a flash memory chip, an electrically erasable and programmable RAM (EEPROM) chip, a phase-change RAM (PRAM) chip, a magnetic RAM (MRAM) chip, or a resistive RAM (RRAM) chip. In some embodiments, the first semiconductor chip 110 may be, for example, a central processing unit (CPU) chip, a graphics processing unit (GPU) chip, or an application processor (AP) chip.

In some embodiments, the first semiconductor chip 110 may be a high bandwidth memory (HBM) DRAM semiconductor chip. In some embodiments, the first semiconductor chip 110 may include a buffer chip including a serial-parallel conversion circuit. In some embodiments, the first semiconductor chip 110 may be a buffer chip for controlling an HBM DRAM semiconductor chip. When the first semiconductor chip 110 is a buffer chip for controlling an HBM DRAM semiconductor chip, the first semiconductor chip 110 may be referred to as a master chip, and the HBM DRAM semiconductor chip may be referred to as a slave chip.

In FIG. 2, the first upper surface connection pad 112a is illustrated as buried within the first semiconductor substrate 111, but is not limited thereto. In some embodiments, the first upper surface connection pad 112a may protrude from a surface of the first semiconductor substrate 111.

In the inventive concept, the first semiconductor substrate 111 may include a base substrate formed of or including a semiconductor material, various conductive material layers formed on the base substrate and constituting the first semiconductor element 111a, an insulating material layer, a wiring pattern electrically connected to the first semiconductor element 111a, and a wiring via. For example, a main material of the first semiconductor substrate 111 may be a semiconductor material, but the main material of the first semiconductor substrate 111 may not be the only material that forms the semiconductor substrate 111.

The second semiconductor chip 120 may include a second semiconductor substrate 121 including a second semiconductor element 121a formed on an active surface thereof, an inner, or internal, upper surface connection pad 122a and an inner, or internal, lower surface connection pad 122b respectively arranged on the active surface and an inactive surface of the second semiconductor substrate 121, a second through electrode 123 penetrating at least a portion of the second semiconductor substrate 121 and electrically connecting the inner upper surface connection pad 122a to the inner lower surface connection pad 122b, and a second protective insulating layer 125 exposing at least a portion of the inner upper surface connection pad 122a (e.g., having an opening through which at least a portion of the inner upper surface connection pad 122a is exposed) and covering the active surface of the second semiconductor substrate 121. The second protective insulating layer 125 may include or be formed of an inorganic material such as oxide or nitride. For example, the second protective insulating layer 125 may include or may be at least one of silicon oxide and silicon nitride. In some embodiments, the second protective insulating layer 125 may be only silicon nitride.

Additional details of the second semiconductor substrate 121, the inner upper surface connection pad 122a, the inner lower surface connection pad 122b, and the second through electrode 123 may be substantially the same as the first semiconductor substrate 111, the first upper surface connection pad 112a, the first lower surface connection pad 112b, and the first through electrode 113, respectively, and thus, detailed descriptions thereof are omitted.

The second semiconductor chip 120 may be or may include, for example, a DRAM chip, an SRAM chip, a flash memory chip, an EEPROM chip, a PRAM chip, an MRAM chip, or an RRAM chip. In some embodiment, the second semiconductor chip 120 may be an HBM DRAM semiconductor chip. In some embodiments, the first semiconductor chip 110 may be referred to as a master chip, and the second semiconductor chip 120 may be referred to as a slave chip.

An inner connection terminal 124 may be attached on the inner upper surface connection pad 122a of each of the plurality of second semiconductor chips 120. The inner connection terminal 124 may electrically connect between the first lower surface connection pad 112b of the first semiconductor chip 110 and the inner upper surface connection pad 122a of the second semiconductor chip 120, and between the inner lower surface connection pad 122b and the inner upper surface connection pad 122a of each of the second semiconductor chips 120, which are vertically adjacent to each other.

The inner connection terminal 124 may include an inner conductive pillar 124a on the inner upper surface connection pad 122a and an inner conductive cap 124b on the inner conductive pillar 124a. It should be noted that certain elements described herein are described in singular, but as can be seen in the figures, are provided in plural. Also, it should be noted that certain terms, such as “inner,” “upper,” “first,” “second,” etc., are used for naming purposes, and may include a descriptive term that refers to a particular component in relation to another component. For example, an “inner” pad may be internal with respect to the first semiconductor device 100, but may actually be an outer pad of an individual semiconductor chip within the first semiconductor device 100.

A width (e.g., in the Y-direction) and an area of the first semiconductor chip 110 may be greater than those of each of the plurality of second semiconductor chips 120. The first semiconductor chip 110 may also have a thickness (e.g., in a Z-direction) greater than a thickness of the each of the second semiconductor chips 120. The first semiconductor device 100 may further include a molding layer 130, disposed on the first semiconductor chip 110, and which surrounds side surfaces of the plurality of second semiconductor chips 120, and side surfaces and a top surface of an underfill fillet 135 to be described below. The molding layer 130 may include or be formed of, for example, an epoxy mold compound (EMC).

An underfill layer 135uf may be arranged between the first semiconductor device 100 and the second semiconductor chip 120 at the lowermost end of the stack of second semiconductor chips 120, and between the plurality of second semiconductor chips 120.

The underfill layer 135uf between the first semiconductor chip 110 and the second semiconductor chip 120 at the lowermost end may surround the inner connection terminal 124, and fill a space between the first semiconductor chip 110 and the second semiconductor chip 120 at the lowermost end. The underfill layer 135uf may extend, in the horizontal direction, between the first semiconductor chip 110 and the second semiconductor chip 120 at the lowermost end, and may be connected to the underfill fillet 135 at the side surfaces of the second semiconductor chips 120 at the lowermost end. The underfill layer 135uf and the underfill fillet 135 may form one body. The underfill fillet 135 may be described as an outer wall structure, or outer wall, or may be referred to as a fence structure or fence. As used herein, the underfill fillet 135 refers to the outer wall structure of underfill material surrounding the stack of second semiconductor chips 120, and the underfill layer 135uf refers to underfill material filled vertically between stacked semiconductor chips. The term “underfill structure” or “filler structure” is used herein to refer to the combination of the underfill fillet 135 and the underfill layer 135uf, which in combination may be formed of the same material throughout and may form a stacked set of horizontal layers formed between four outer sidewalls, which may be referred to as “underfill sidewalls.” The underfill sidewalls, or underfill fillet 135, may be formed around the underfill layers 135uf to surround the underfill layers 135uf from a plan view.

The underfill layer 135uf may be provided for improving adhesion strength of each component and/or preventing each component from physical strength deterioration due to deformation. In some embodiments, a reason that the underfill layer 135uf is provided may be, for example, for removing a space, into which a foreign material or moisture infiltrates, and preventing electrical migration.

In some embodiments, the underfill layer 135uf may include or be formed of a bisphenol-A (BPA) epoxy resin, a bisphenol-F (BPF) epoxy resin, an aliphatic epoxy resin, a cycloaliphatic epoxy resin, etc. In some embodiments, the underfill layer 135uf may further include inorganic particles of one or more types selected from silica, alumina, zirconia, titania, ceria, magnesia, silicon carbide, and Aluminum nitride.

The underfill layer 135uf may be arranged between two adjacent second semiconductor chips 120. The underfill layer 135uf between the two adjacent second semiconductor chips 120 may surround the inner connection terminal 124, and fill a space between the two adjacent second semiconductor chips 120. In addition, the underfill layer 135uf may extend between the plurality of second semiconductor chips 120 in the horizontal direction, and be connected to the underfill fillet 135 at the side surfaces of the plurality of second semiconductor chips 120.

The side surfaces of the underfill fillet 135 may be completely covered by the molding layer 130. For example, the underfill fillet 135 may not be exposed to the outside of the first semiconductor device on the side surfaces of the molding layer 130.

In some embodiments, an upper semiconductor chip 120T at the uppermost portion among the plurality of second semiconductor chips 120 may not include the inner lower surface connection pad 122b and the second through electrode 123. In some embodiments, a thickness of the upper semiconductor chip 120T may be greater than a thickness of each of the other plurality of second semiconductor chips 120.

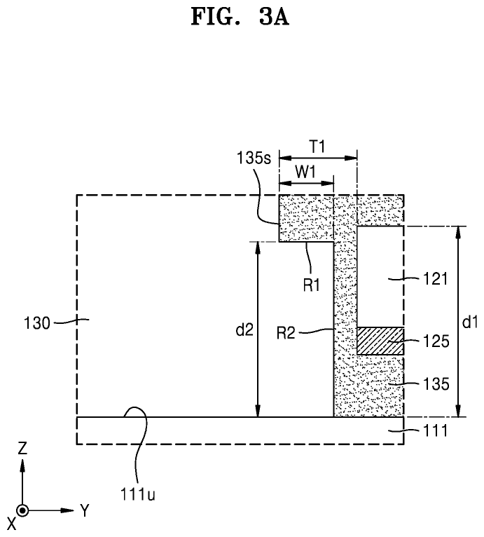

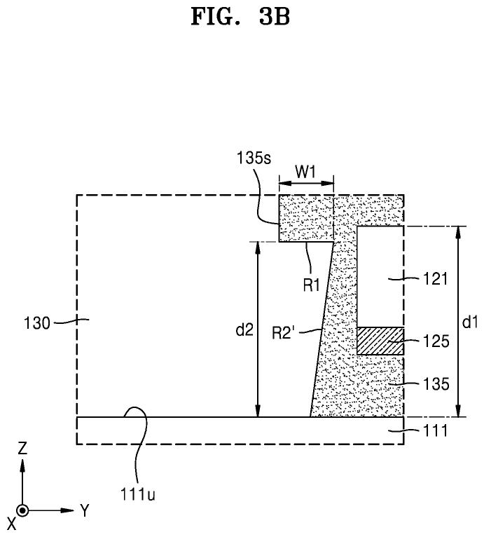

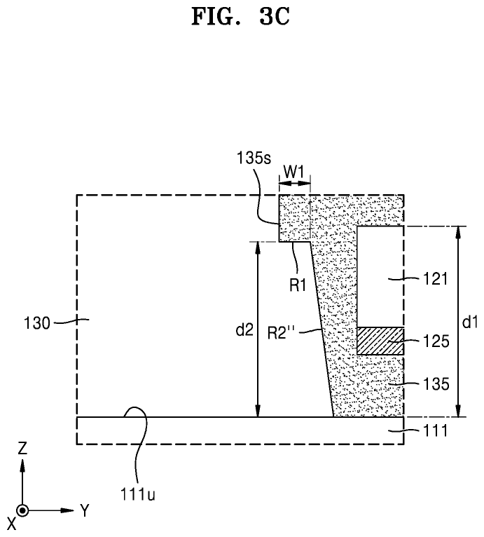

The underfill fillet 135 may include a recess pattern R at locations where the underfill fillet 135 meets the first semiconductor chip 110. Descriptions on this issue are given in detail below with reference to FIGS. 3A through 3C.

Referring to FIG. 1 again, the second semiconductor device 200 may include a third semiconductor substrate 210, the second upper surface connection pad 242, a third protective insulating layer 245, and the second connection terminal 244. The second connection terminal 244 may include the second conductive pillar 244a on the second upper surface connection pad 242 and a second conductive cap 244b on the second conductive pillar 244a. The third semiconductor substrate 210, the second upper surface connection pad 242, the third protective insulating layer 245, and the second connection terminal 244 may respectively include components substantially the same as or similar to the first semiconductor substrate 111, the first upper surface connection pad 112a, the first protective insulating layer 115, and the first connection terminal 114, or may respectively include components substantially the same as or similar to the second semiconductor substrate 121, the inner upper surface connection pad 122a, the second protective insulating layer 125, and the inner connection terminal 124, and thus, detailed descriptions thereof are omitted.

The second semiconductor device 200 may include or may be, for example, a CPU chip, a GPU chip, or an AP chip.

The first substrate 300 may include a base layer 310, a redistribution structure 357 arranged on a first surface 312 of the base layer 310, and a plurality of pad wiring layers 324 arranged on a second surface 314 of the base layer 310. The redistribution structure 357 may include a redistribution insulating layer 357_6, and the plurality of first redistribution pads 357_2 and a plurality of second redistribution pads 357_4, which are arranged on both surfaces of the redistribution insulating layer 357_6. Accordingly, the plurality of first redistribution pads 357_2 may be arranged on an upper surface of the first substrate 300, and the plurality of pad wiring layers 324 may be arranged on a lower surface of the first substrate 300.

The base layer 310 may be or may include a semiconductor material, glass, ceramic, or plastic. For example, the base layer 310 may be silicon. In some embodiments, the base layer 310 may be formed from a silicon semiconductor substrate. A plurality of first substrate through electrodes 330 connecting between the first surface 312 and the second surface 314 may be arranged inside the base layer 310. Each of the plurality of first substrate through electrodes 330 may include or be formed of a conductive plug penetrating the base layer 310 and a conductive barrier layer surrounding the conductive plug. The conductive plug may have a circular shape, and the conductive barrier layer may have a cylindrical shape surrounding sidewalls of the conductive plug. A plurality of via insulation layers may be arranged between the base layer 310 and the plurality of first substrate through electrodes 330, and surround sidewalls of the plurality of first substrate through electrodes 330.

The redistribution structure 357 may include the redistribution insulating layer 357_6, and the plurality of first redistribution pads 357_2 and a plurality of second redistribution pads 357_4, which are arranged on both surfaces of the redistribution insulating layer 357_6. The plurality of second redistribution pads 357_4 may be arranged on the first surface 312 of the base layer 310, and may be electrically connected to the plurality of first substrate through electrodes 330. The plurality of first substrate through electrodes 330 may electrically connect between the plurality of second redistribution pads 357_4 and the plurality of pad wiring layers 324.

The redistribution structure 357 may further include a plurality of redistribution lines 357_7 and a plurality of redistribution vias 357_8, which electrically connect the plurality of first redistribution pads 357_2 to the plurality of second redistribution pads 357_4. In FIG. 1, the plurality of redistribution lines 357_7 are illustrated as being inside the redistribution insulating layer 357_6, but are not limited thereto.

For example, each of the plurality of first redistribution pads 357_2, the plurality of second redistribution pads 357_4, the plurality of redistribution lines 357_7, and the plurality of redistribution vias 357_8 may include or may be formed of copper, nickel, stainless steel, or a copper alloy such as beryllium copper. For example, the redistribution insulating layer 357_6 may include or be formed of at least one of oxide, nitride, and photo imageable dielectric (PID). In some embodiments, the redistribution insulating layer 357_6 may include or be formed of silicon oxide, silicon nitride, epoxy, or polyimide.

On the second surface 314 of the base layer 310, a first substrate protective layer 355, the plurality of pad wiring layers 324 arranged on the first substrate protective layer 355 and connected to the plurality of first substrate through electrodes 330 penetrating the first substrate protective layer 355, a plurality of first substrate connection terminals 340 arranged on the plurality of pad wiring layers 324, and a plurality of wiring protection layers 356, which surround the plurality of first substrate connection terminals 340 and cover the plurality of pad wiring layers 324 may be arranged.

The first substrate 300 may be an interposer.

A first adhesive film layer 382 may be arranged between the first semiconductor device 100 and the first substrate 300, and a second adhesive film layer 384 may be arranged between the second semiconductor device 200 and the first substrate 300. The first adhesive film layer 382 and the second adhesive film layer 384 may surround the first connection terminal 114 and the second connection terminal 244, respectively. In some embodiments, the first adhesive film layer 382 may protrude from the side surfaces of the first semiconductor device 100 in the lateral direction. In some embodiments, the second adhesive film layer 384 may protrude from the side surfaces of the second semiconductor device 200 in the lateral direction.

The second substrate 400 may include a base board layer 410, and a board upper surface pad 422 and a board lower surface pad 424, which are respectively arranged on an upper surface and a lower surface of the base board layer 410. In some embodiments, the second substrate 400 may be a printed circuit board. For example, the second substrate 400 may be a multi-layer printed circuit board. The base board layer 410 may include or be formed of at least one material selected from phenol resin, epoxy resin, and polyimide.

A solder resist layer (not illustrated), which includes openings that expose the board upper surface pad 422 and the board lower surface pad 424, may be formed on the upper surface and the lower surface of the base board layer 410, respectively. The first substrate connection terminal 340 may be connected to the board upper surface pad 422, and a package connection terminal 440 may be connected to the board lower surface pad 424. The first substrate connection terminal 340 may electrically connect between the plurality of pad wiring layers 324 and the board upper surface pads 422. The package connection terminal 440 connected to the board lower surface pad 424 may connect the semiconductor package 1 to an external device.

The package connection terminal 440 may have greater dimensions (for example, a diameter) than the plurality of first connection terminals 114, the plurality of second connection terminals 244, and the first substrate connection terminal 340. In addition, the first substrate connection terminal 340 may have greater dimensions (for example, a diameter) than the plurality of first connection terminals 114 and the plurality of second connection terminals 244.

A board adhesive film layer 380 may be arranged between the first substrate 300 and the second substrate 400. The board adhesive film layer 380 may surround the plurality of first substrate connection terminals 340.

The semiconductor package 1 may further include, on the first substrate 300, a package molding layer 800, which surrounds the side surfaces of the first semiconductor device 100 and the second semiconductor device 200. The package molding layer 800 may include or be formed of, for example, EMC.

In some embodiments, the package molding layer 800 may cover the upper surface of the first substrate 300 and the side surface of each of the first semiconductor device 100 and the second semiconductor device 200, but may not cover the upper surfaces of the first semiconductor device 100 and the second semiconductor device 200. In this case, the semiconductor package 1 may further include a heat dissipating member 950, which covers the upper surfaces of the first semiconductor device 100 and the second semiconductor device 200. The heat dissipating member 950 may include or may be a heat dissipating plate such as a heat slug or a heat sink. In some embodiments, the heat dissipating member 950 may, on an upper surface of the second substrate 400, surround the upper surfaces and the side surfaces of the first semiconductor device 100, the second semiconductor device 200, and the first substrate 300. In some embodiments, the heat dissipating member 950 may include or may be a flat plate or a solid of a metal material.

In some embodiments, the heat dissipating member 950 may block an electronic wave and dissipate heat, and may be connected to a board upper surface ground pad 422g, which provides ground among the plurality of board upper surface pads 422 of the second substrate 400.

The semiconductor package 1 may include a thermal interface material (TIM) 900 arranged between the heat dissipating member 950, and the first semiconductor device 100 and the second semiconductor device 200. The TIM 900 may include paste, film, etc.

FIGS. 3A through 3C are partially enlarged views of region A1 in FIG. 2, according to example embodiments.

Referring to FIG. 3A, the recess pattern R may be recessed in a direction in parallel with an upper surface 111u of the first semiconductor chip 110. In some embodiments, the recess pattern R may extend along a periphery of the second semiconductor chips 120 at the lowermost location among the plurality of second semiconductor chips 120.

In some embodiments, the recess pattern R may include a first surface R1, which faces the upper surface 111u of the first semiconductor chip 110 and extends toward the plurality of second semiconductor chips 120 (that is, in a Y direction as depicted in FIG. 3A). In some embodiments, the first surface R1 may be substantially parallel to the upper surface 111u of the first semiconductor chip 110. In this case, that the upper surface 111u is ‘substantially parallel to’ the first surface R1 may mean that they are completely in parallel with each other, or they are slanted in relation to each other up to within about 5 degrees)(°) .

In some embodiments, a width W1 of the first surface R1 may be about 3 μm to about 40μm. In some embodiments, the width W1 of the first surface R1 may be within a range from about 3 μm to about 40 μm, about 4 μm to about 38 μm, about 5 μm to about 36 μm, about 6 μm to about 34 μm, about 7 μm to about 32 μm, about 8 μm about to 30 μm, about 9 μm to about 28 μm, about 10 μm to about 25 μm, or any range between these values. Terms such as “about” or “approximately” may reflect amounts, sizes, orientations, or layouts that vary only in a small relative manner, and/or in a way that does not significantly alter the operation, functionality, or structure of certain elements.

In addition, the recess pattern R may include a second surface R2 connecting the first surface R1 to the upper surface 111u of the first semiconductor chip 110. In some embodiments, the second surface R2 may be a flat surface rather than a curved surface.

In some embodiments, the underfill fillet 135 may contact the molding layer 130 on the second surface R2. The second surface R2 may be substantially vertical with respect to the upper surface 111u of the first semiconductor chip 110. In this case, that the second surface R2 is ‘substantially vertical with respect to’ the upper surface 111u may mean that the second surface R2 is completely vertical with respect to the upper surface 111u, or make an angle of about 85 degrees) (° to about 95 degrees)(° . The term “contact,” as used herein, refers to a direct connection (i.e., touching) unless the context indicates otherwise.

In some embodiments, a distance d2 between the first surface R1 and the upper surface 111u of the first semiconductor chip 110 may be about 0.5 times to about 1.8 times a distance d1 between an upper surface of the second semiconductor chip 120 at the lowermost location among the plurality of second semiconductor chips 120 and the upper surface 111u. In some embodiments, the distance d2 between the first surface R1 and the upper surface 111u of the first semiconductor chip 110 may be in a range from about 0.5 times to about 1.8 times, about 0.6 times to about 1.7 times, about 0.7 times to about 1.6 times, about 0.8 times to about 1.5 times, about 0.9 times to about 1.4 times, about 1.0 times to about 1.3 times the distance d1 between the upper surface of the second semiconductor chip 120 at the lowermost location among the plurality of second semiconductor chips 120 and the upper surface 111u, or any range between these values. Amounts within these ranges and within the ranges described previously and below may result from using a dam structure, described further below, of a sufficient size to limit movement of the underfill fillet 135 in a lateral direction, while maintaining the ability to adequately stack the semiconductor chips 120.

In some embodiments, the distance d2 between the first surface R1 and the upper surface 111u of the first semiconductor chip 110 may be about 20 μm to about 100μm. In some embodiments, the distance d2 between the first surface R1 and the upper surface 111u of the first semiconductor chip 110 may be in a range from about 20 μm to about 100 μm, about 25 μm to about 95 μm, about 30 μm to about 90 μm, about 35 μm to about 85 μm, about 40 μm to about 80 μm, about 45 μm about to 75 μm, about 50 μm to about 70 μm, about 55 μm to about 65 μm, or may have any range between these values.

In some embodiments, at an upper portion of the recess pattern R, the underfill fillet 135 may include an outside surface 135s, which is a flat surface extending in a direction substantially vertical with respect to the upper surface 111u of the first semiconductor chip 110 (e.g., in a Z direction). A first thickness T1 of a portion of the underfill fillet 135 extending in the Z direction at the upper portion of the recess pattern R may be about 40 μm to about 300 μm. In some embodiments, the first thickness T1 may be in a range from about 40 μm to about 300 μm, about 60 μm to about 290 μm, about 80 μm to about 280 μm, about 100 μm to about 260 μm, about 120 um to about 240 μm, about 140 μm to about 220 μm, about 160 μm to about 200 μm, or any range between these values.

When the first thickness T1 is too large, it may be difficult to fabricate the first semiconductor device 100 in a compact manner. When the first thickness T1 is too small, a mechanical strength thereof may be too low.

Referring to FIGS. 2 and 3A, the recess pattern R may include a pattern formed by a dam structure 140 to be described below. It should be noted that although the recess extending in the Y-direction is shown, the recess may be disposed along all four sides of the first semiconductor device 100, and so from a different viewpoint, the recess may extend in the X-direction. For example, on each side of the underfill fillet 135, the recess pattern R may extend in a direction toward the second semiconductor chips 120, and may also extend along a side surface, or edge, of at least one of the second semiconductor chips 120. The recess may be formed below an overhanging portion of the underfill fillet 135 and may be filled with a protruding portion of the molding layer 130 protruding toward a side surface of the second semiconductor chips 120.

Referring to FIG. 3B, the embodiment shown may be the same as the embodiment described with reference to FIG. 3A, except for that a second surface R2′ is slanted so that the first surface R1 and the second surface R2′ make an acute angle. Thus, descriptions are given below mainly based on this difference.

The second surface R2′ may, as a flat surface, have an angle of about 55 degrees)(°)to about 80 degrees)(°) with respect to the first surface R1. In some embodiments, the angle, which the second surface R2′ and the first surface R1 make, may be adjusted so that a lower end of the second surface R2′ does not protrude outwardly beyond the outside surface 135s of the underfill fillet 135 (e.g., in a horizontal direction).

Referring to FIGS. 2 and 3B, the first surface R1 and the second surface R2′ may have patterns formed by the dam structure 140 to be described below. Accordingly, the dam structure 140 may have a shape corresponding to the first surface R1 and the second surface R2′, and may somewhat delay an overflow of the underfill fillet 135 due to the slanted inner side surface.

Referring to FIG. 3C, the embodiment shown may be the same as the embodiment described with reference to FIG. 3B, except for that a second surface R2″ is slanted so that the first surface R1 and the second surface R2″ make an obtuse angle. Thus, descriptions are given below mainly based on this difference.

The second surface R2″ may, as a flat surface, have an angle of about 100 degrees)(°) to about 125 degrees)(°) with respect to the first surface R1. In some embodiments, the angle, which the second surface R2″ and the first surface R1 make, may be adjusted so that the width W1 of the first surface R1 is not too small (e.g., not below a threshold amount).

Referring to FIGS. 2 and 3C, the first surface R1 and the second surface R2″ may have patterns formed by the dam structure 140 to be described below. Accordingly, the dam structure 140 may have a shape corresponding to the first surface R1 and the second surface R2″, and may somewhat delay an overflow of the underfill fillet 135 due to the slanted inner side surface.

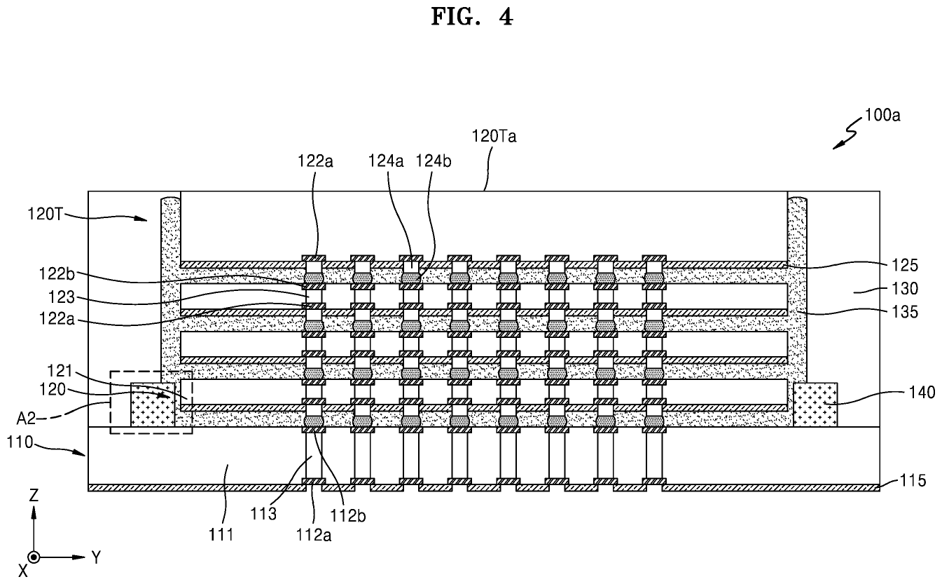

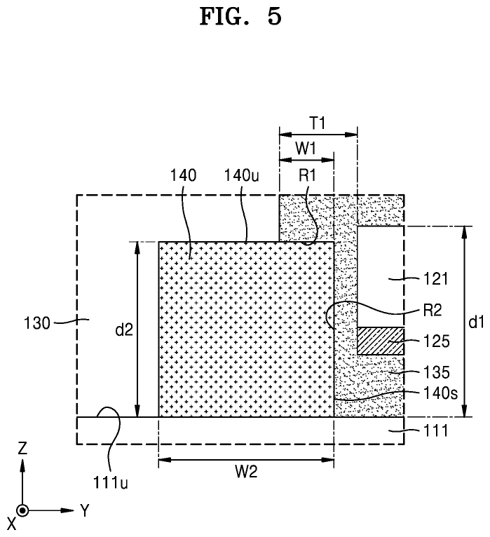

FIG. 4 is a cross-sectional view of a first semiconductor device 100a included in a semiconductor package, according to another embodiment. FIG. 5 is a partially enlarged view of region A2 in FIG. 4.

The first semiconductor device 100a illustrated in FIG. 4 may be the same as the first semiconductor device 100 described with reference to FIG. 2, except that the dam structure 140 is further included. Accordingly, hereinafter, the first semiconductor device 100a is described below mainly based on this difference.

Referring to FIGS. 4 and 5, the first semiconductor device 100a may further include the dam structure 140. The dam structure 140 may be arranged to match the recess pattern R.

In some embodiments, the dam structure 140 may contact the first surface R1 and the second surface R2 of the recess pattern R. In some embodiments, an upper surface 140u of the dam structure 140 may form the same plane as the first surface R1. In some embodiments, an inner side surface 140s of the dam structure 140 may contact the second surface R2 over the entire area thereof.

A height of the dam structure 140 may be the same as the distance d2 between the first surface R1 and the upper surface 111u of the first semiconductor chip 110 as described with reference to FIG. 3A. For example, the height of the dam structure 140 may be in a range from about 20 μm to about 100 μm, about 25 μm to about 95 μm, about 30 μm to about 90 μm, about 35 μm to about 85 μm, about 40 μm to about 80 μm, about 45 μm to about 75 μm, about 50 μm to about 70 μm, about 55 μm to about 65 μm, or any range between these values.

When the height of the dam structure 140 is too small, a function thereof for limiting a movement in a lateral direction of the underfill fillet may be deteriorated. In addition, when the height of the dam structure 140 is too large, it may be difficult to stack the plurality of second semiconductor chips 120.

The dam structure 140 may, like the recess pattern R, extend along a periphery of the second semiconductor chip 120 at the lowermost location among the plurality of second semiconductor chips 120. A width W2 of the dam structure 140 may be about 200 μm to about 1200 μm. For example, the dam structure 140 may have four sides from a plan view, and a width W2 of one side may be between about 200 μm and about 1200 μm in a direction parallel to the upper surface of the substrate of the semiconductor chip 110. In some embodiments, the width W2 of the dam structure 140 may be in a range from about 200 μm to about 1200 μm, about 250 μm to about 1150 μm, about 300 μm to about 1100 μm, about 350 μm to about 1050 μm, about 400to about 1000 μm, about 450 μm to about 950 μm, about 500 μm to about 900 μm, about 550to about 850 μm, about 600 μm to about 800 μm, or any range between these values.

When the width W2 of the dam structure 140 is too large, it may be difficult to fabricate the first semiconductor device 100 in a compact manner. When the width W2 of the dam structure 140 is too small, the underfill fillet 135 may overflow to the outside of the dam structure 140.

In some embodiments, the dam structure 140 may include or be formed of a polymer material such as a photoresist and a solder resist, a metal, silicon oxide, or silicon nitride.

In FIG. 5, the inner side surface 140s of the dam structure 140 is illustrated as being vertical to the upper surface 111u of the first semiconductor chip 110, but one of ordinary skill in the art may understand that the inner side surface 140s is allowed to be slanted at an angle with respect to the upper surface 111u so that the second surfaces R′ and R″ respectively in FIGS. 3B and 3C are formed. In some embodiments, the inner side surface 140s may be a flat surface rather than a curved surface. Terms such as “same,” “equal,” “planar,” “coplanar,” “flat,” “parallel,” and “perpendicular,” “vertical,” or “horizontal,” as used herein encompass identicality or near identicality including variations that may occur, for example, due to manufacturing processes. The term “substantially” may be used herein to emphasize this meaning, unless the context or other statements indicate otherwise.

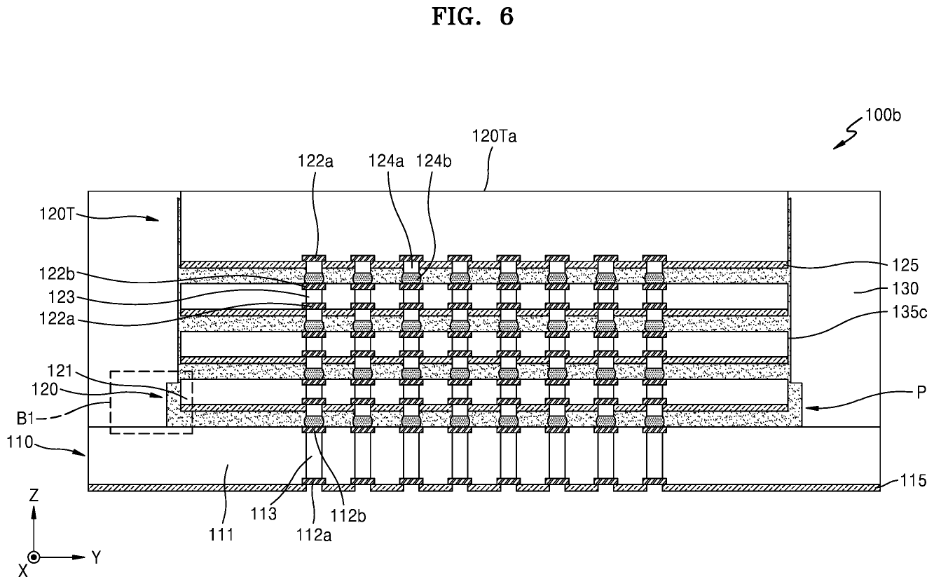

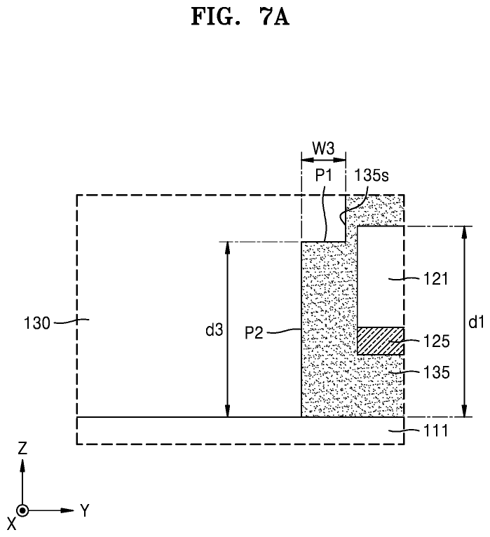

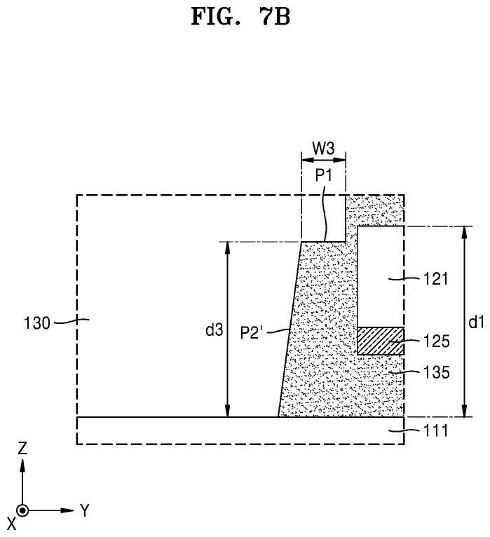

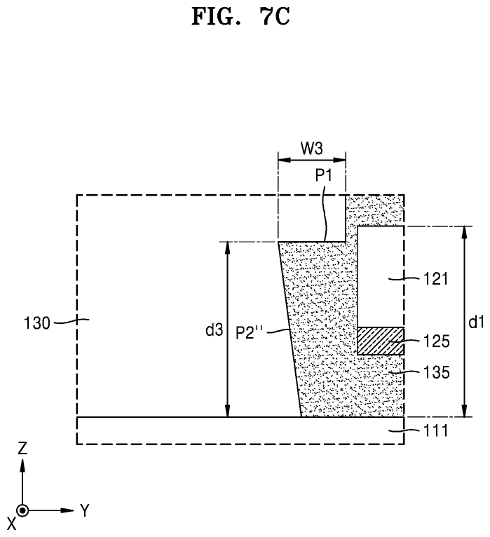

FIG. 6 is a cross-sectional view of a first semiconductor device 100b included in a semiconductor package, according to another embodiment. FIGS. 7A through 7C are partially enlarged views of region B1 in FIG. 6, according to example embodiments.

When the first semiconductor device 100b in the embodiment of FIG. 6 is compared to the first semiconductor device 100 described with reference to FIG. 2, they may be the same as each other except that a protrusion pattern P is included rather than the recess pattern R. Accordingly, hereinafter, the first semiconductor device 100b is described below mainly based on this difference.

Referring to FIGS. 6 and 7A, the protrusion pattern P may protrude in a direction parallel to the upper surface 111u (that is, in a Y direction) at locations where the underfill fillet 135 meets the upper surface 111u of the first semiconductor chip 110. The protrusion pattern P may protrude outward from an outer surface of the second semiconductor chip 120.

The protrusion pattern P may include a first surface P1, which is parallel to the upper surface 111u of the first semiconductor chip 110, and extends in a direction away from the plurality of second semiconductor chips 120 (though a Y direction is shown, it may extend in addition in the X direction, when viewed from a different axis). In addition, the protrusion pattern P may further include a second surface P2 connecting the first surface P1 to the upper surface 111u. In some embodiments, the second surface P2 may be substantially vertical with respect to the upper surface 111u of the first semiconductor chip 110. In some embodiments, the second surface P2 may be a flat surface rather than a curved surface. In some embodiments, the underfill fillet 135 may contact the molding layer 130 on the second surface P2.

The first surface P1 may have a width W3 in a direction away from the plurality of second semiconductor chips 120 (e.g., in the Y direction as shown in FIG. 7A). The width W3 of the first surface P1 may be about 3 μm to about 40 μm. In some embodiments, the width W3 of the first surface P1 may be in a range from about 3 μm to about 40 μm, about 4 μm to about 38 μm, about 5 μm to about 36 μm, about 6 μm to about 34 μm, about 7 μm to about 32 μm, about 8 μm about to 30 μm, about 9 μm to about 28 μm, about 10 μm to about 25 μm, or any range between these values.

In some embodiments, a distance d3 between the first surface P1 and the upper surface 111u of the first semiconductor chip 110 may be about 0.5 times to about 1.8 times a distance d1 between the upper surface of the second semiconductor chip 120 at the lowermost location among the plurality of second semiconductor chips 120 and the upper surface 111u. In some embodiments, the distance d3 between the first surface P1 and the upper surface 111u of the first semiconductor chip 110 may be in a range from about 0.5 times to about 1.8 times, about 0.6 times to about 1.7 times, about 0.7 times to about 1.6 times, about 0.8 times to about 1.5 times, about 0.9 times to about 1.4 times, about 1.0 times to about 1.3 times the distance d1 between the upper surface of the second semiconductor chip 120 at the lowermost location among the plurality of second semiconductor chips 120 and the upper surface 111u, or any range between these values .

In some embodiments, the distance d3 between the first surface P1 and the upper surface 111u of the first semiconductor chip 110 may be about 20 μm to about 100 μm. In some embodiments, the distance d3 between the first surface P1 and the upper surface 111u of the first semiconductor chip 110 may be about 20 μm to about 100 μm, about 25 μm to about 95 μm, about 30 μm to about 90 μm, about 35 μm to about 85 μm, about 40 μm to about 80 μm, about 45 μm about to 75 μm, about 50 μm to about 70 μm, about 55 μm to about 65 μm, or any range between these values.

Referring to FIG. 7B, the embodiment shown may be the same as the embodiment described with reference to FIG. 7A, except that a second surface P2′ is slanted so that the first surface P1 and the second surface P2′ make an obtuse angle. Thus, descriptions are given below mainly based on this difference.

The second surface P2′ may, as a flat surface, have an angle of about 100 degrees)(°) to about 125 degrees)(°) with respect to the first surface P1. When an angle, which the second surface P2′ and the first surface P1 make, is too large, it may be difficult to fabricate the first semiconductor device 100b in a compact manner.

Referring to FIG. 7C, the embodiment shown may be the same as the embodiment described with reference to FIG. 7B, except that a second surface P2″ is slanted so that the first surface P1 and the second surface P2″ make an acute angle. Thus, descriptions are given below mainly based on this difference.

The second surface P2″ may, as a flat surface, have an angle of about 55 degrees)(°) to about 80 degrees)(°) with respect to the first surface P1. When an angle, which the second surface P2″ and the first surface P1 make, is too large, it may be difficult to fabricate the first semiconductor device 100b in a compact manner.

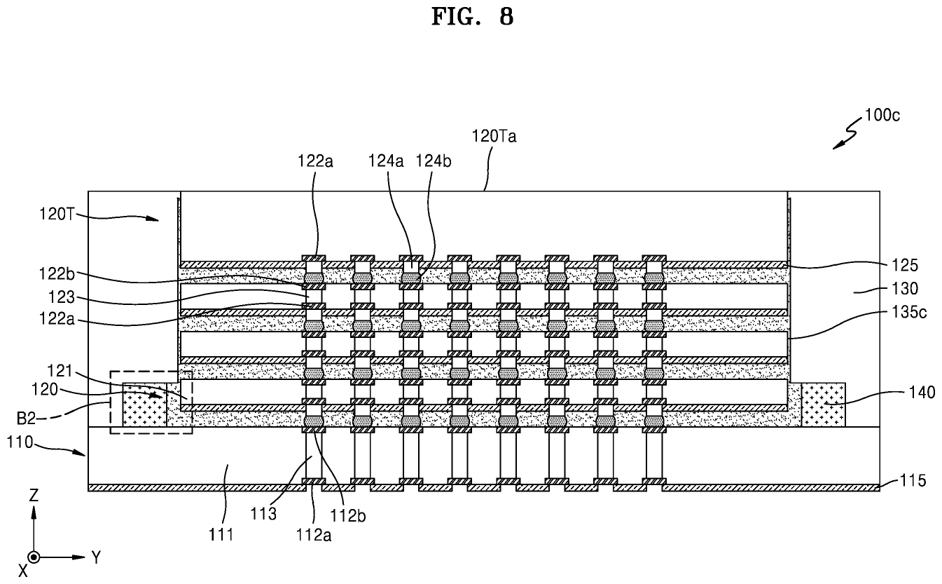

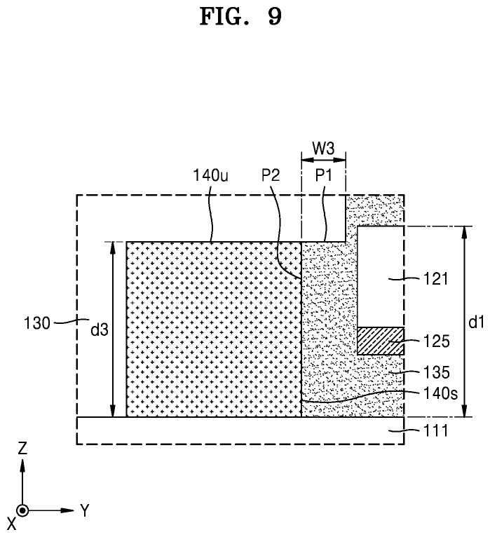

FIG. 8 is a cross-sectional view of a first semiconductor device 100c included in a semiconductor package, according to another embodiment. FIG. 9 is a partially enlarged view of region B2 in FIG. 8.

The first semiconductor device 100c illustrated in FIG. 8 may be the same as the first semiconductor device 100b described with reference to FIG. 6, except for that the dam structure 140 is further included. Accordingly, the first semiconductor device 100c is described below mainly based on this difference.

Referring to FIGS. 8 and 9, the first semiconductor device 100c may further include the dam structure 140. The dam structure 140 may be arranged adjacent to the protrusion pattern P.

In some embodiments, the dam structure 140 may contact the second surface P2 of the protrusion pattern P. In some embodiments, an upper surface 140u of the dam structure 140 may be arranged on the same flat surface as the first surface P1 (e.g., to be coplanar with the first surface P1). In some embodiments, an inner side surface 140s of the dam structure 140 may contact the second surface P2 over the entire area thereof.

In FIG. 9, the inner side surface 140s of the dam structure 140 is illustrated as being vertical to the upper surface 111u of the first semiconductor chip 110, but one of ordinary skill in the art may understand that the inner side surface 140s is allowed to be slanted at an angle with respect to the upper surface 111u so that the second surfaces P′ and P″ respectively in FIGS. 7B and 7C are formed.

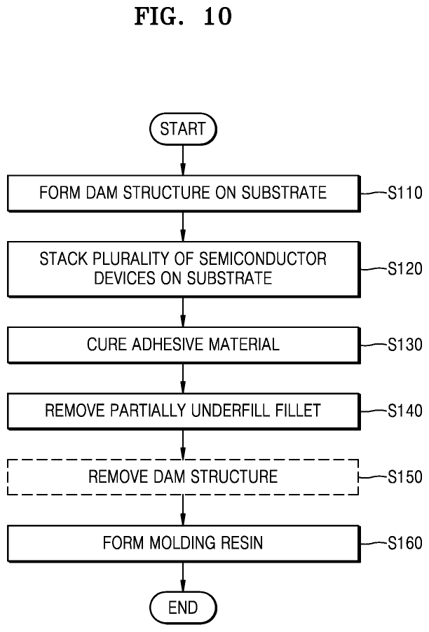

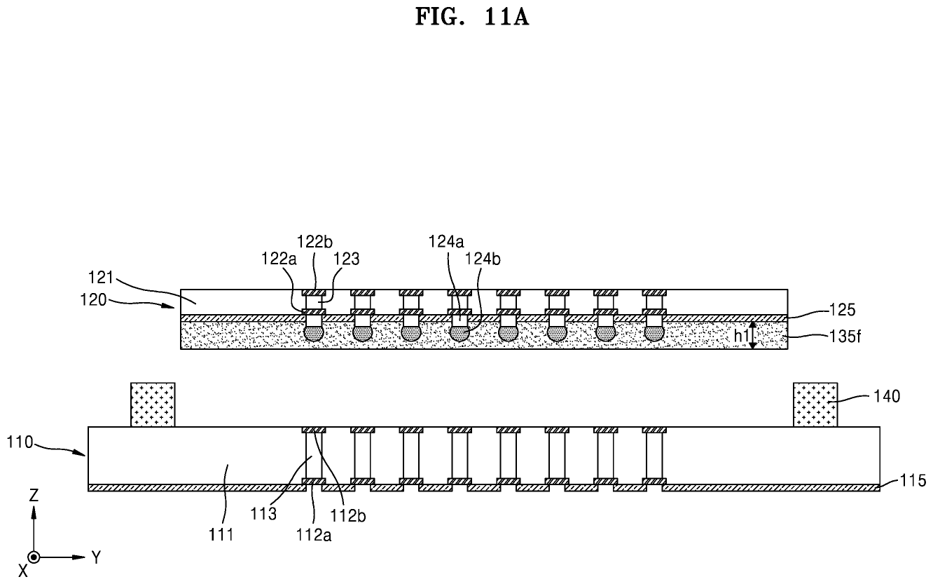

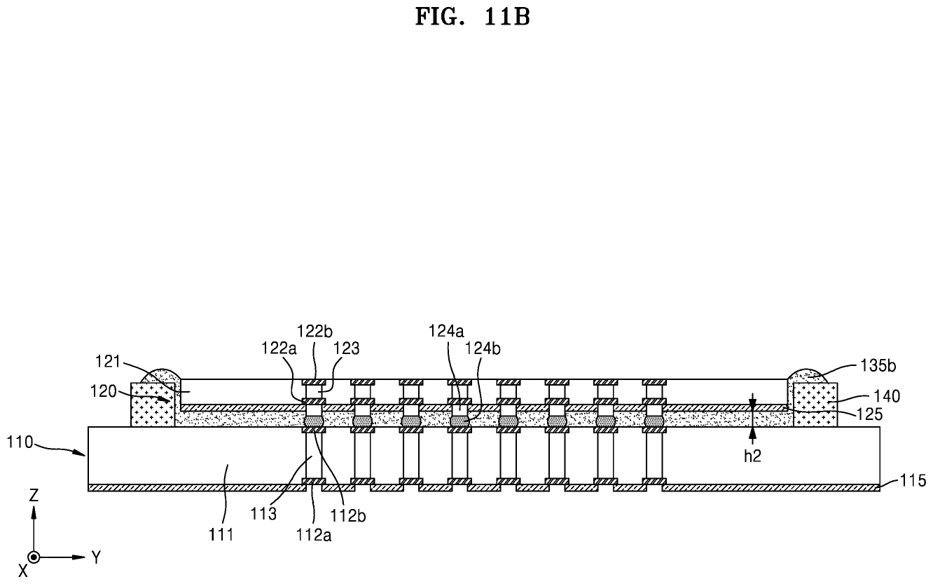

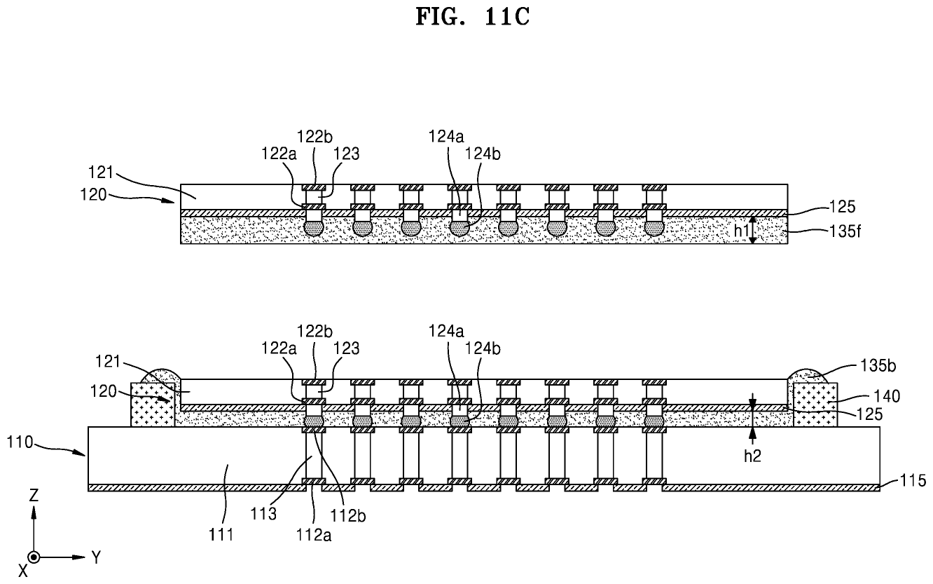

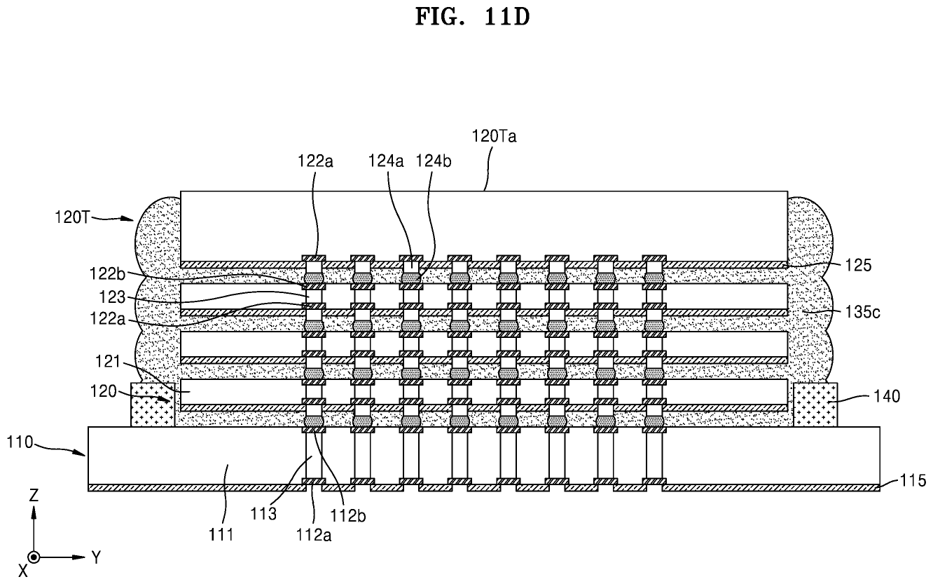

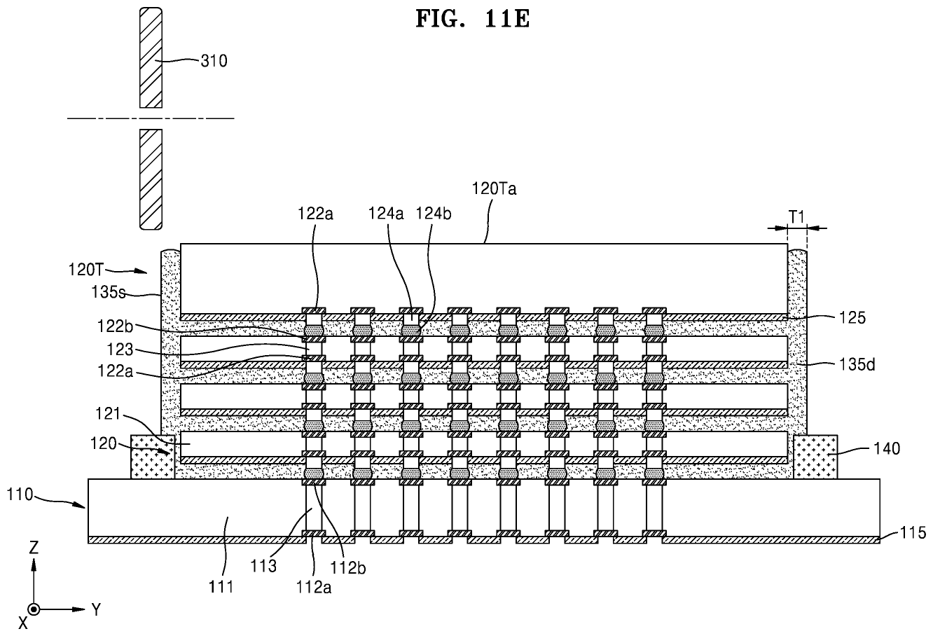

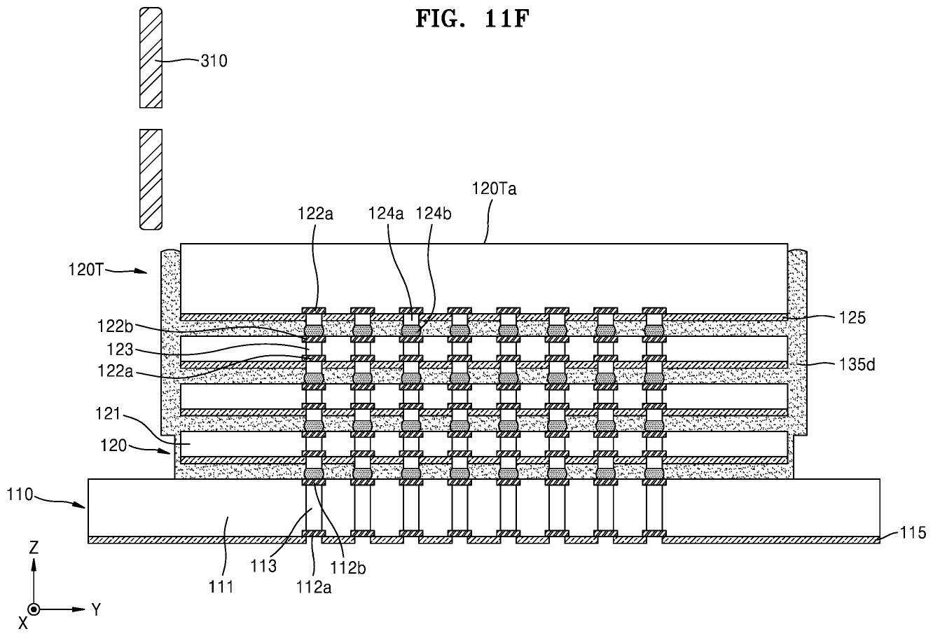

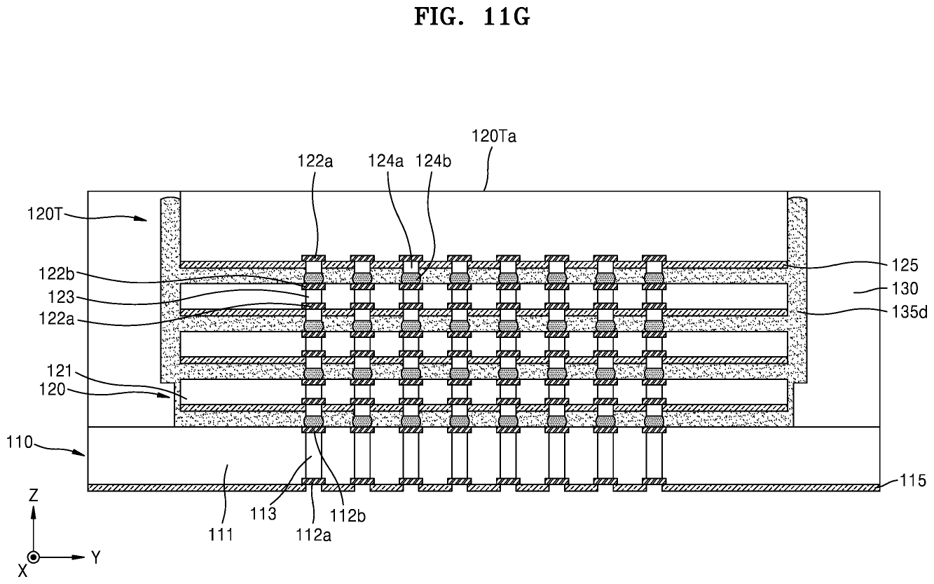

FIG. 10 is a flowchart of a method of fabricating a semiconductor package, according to an example embodiment. FIGS. 11A through 11G are side views illustrating a method of fabricating a semiconductor package, according to example embodiments.

Referring to FIGS. 10 and 11A, the dam structure 140 may be formed on the first semiconductor chip 110, which serves as a substrate (S110). The dam structure 140 may be provided on the first semiconductor chip 110 around locations where the plurality of second semiconductor chips 120 are to be stacked. Dimensions of the dam structure 140 have been described in detail with reference to FIGS. 4, 5, or the like, and thus, detailed descriptions thereof are omitted here. Though shown from a cross-sectional view, the dam structure 140 may have a rectangular shape from a plan view.

In some embodiments, the dam structure 140 may be formed by depositing a photosensitive material such as a photoresist on the first semiconductor chip 110, and then performing exposure and development. In some embodiments, the dam structure 140 may be formed by forming a sacrifice mold, then depositing silicon oxide or silicon nitride by using a chemical vapor deposition process or a physical vapor deposition process, and removing the sacrifice mold. In some embodiments, the dam structure 140 may be formed by forming a sacrifice mold, then forming a metal pattern by using an electroplating process or a non-electrolytic plating process, and removing the sacrifice mold.

Thereafter, the second semiconductor chip 120 is attached to the first semiconductor chip 110 (S120). In FIG. 11A, the first semiconductor chip 110 is illustrated as in a cut state, but in some embodiments, the first semiconductor chip 110 may include a portion of a semiconductor wafer that fits inside of the dam structure 140, which has not been singulated yet.

The second semiconductor chip 120 may include a non-conductive film (NCF) 135f as an adhesive material on the second protective insulating layer 125. The NCF 135f may have a thickness h1, which is sufficient enough to bury the inner conductive pillar 124a and the inner conductive cap 124b. Here, an example is illustrated, in which the NCF 135f is provided as an adhesive material on the second protective insulating layer 125, but one of ordinary skill in the art may understand that non-conductive paste or a general underfill material may be used as an adhesive material instead of the NCF 135f.

In some embodiments, the NCF 135f may further include inorganic particles of one or more types selected from silica, alumina, zirconia, titania, ceria, magnesia, silicon carbide, and aluminum nitride.

Referring to FIGS. 10 and 11B, after the second semiconductor chip 120 is attached on the first semiconductor chip 110, which is a substrate, heat and pressure may be applied so that the NCF 135f has liquidity. When pressure is applied, due to the liquidity, the NCF 135f may form an underfill fillet 135b, which moves outwardly from the side surfaces of the second semiconductor chips 120 and protrudes upwardly from the dam structure 140. The portion of the NCF 135f that overlaps the second semiconductor chips 120 from a plan view may be described as an underfill layer (e.g., 135uf in FIG. 2), and a the portion of the NCF 135f that moves, due to pressure, to end up outside of the area occupied by the second semiconductor chips 120 from a plan view, may be described as the underfill fillet 135b (described as item 135 in FIG. 2).

When the inner conductive cap 124b of the second semiconductor chip 120 contacts the first lower surface connection pad 112b of the first semiconductor chip 110 and reflows due to heat, the first semiconductor chip 110 may be adhered to the second semiconductor chip 120. After the first semiconductor chip 110 is adhered to the second semiconductor chip 120, a distance h2 therebetween may be less than the thickness h1 of the NCF 135f before adhesion. Thus, a significant portion of a volume of the NCF 135f may protrude toward an upper portion of the underfill fillet 135b.

In some embodiments, the upper end of the underfill fillet 135b may move higher than a surface of the second semiconductor chip 120.

Referring to FIGS. 10 and 11C, one additional second semiconductor chip 120 may be further stacked on the second semiconductor chip 120. Thereafter, after heat and pressure is applied, the inner conductive cap 124b of the second semiconductor chip 120 contacts the inner lower surface connection pad 122b, and reflows due to heat, two second semiconductor chips 120 may be adhered to each other. As described with reference to FIG. 11B, a significant portion of the volume of the NCF 135f may protrude as an underfill fillet.

After repeating the above-described processes, as illustrated in FIG. 11D, the plurality of second semiconductor chips 120 may be stacked on the first semiconductor chip 110, and a structure, in which an underfill fillet 135c protrudes in a lateral direction and is cured, may be obtained (S130). Although four second semiconductor chips 120 are illustrated in FIG. 11D, eight, sixteen, or more second semiconductor chips 120 may be stacked as necessary.

In some embodiments, the underfill fillet 135c may completely surround the side surfaces of the second semiconductor chips 120 and may also surround outer ends of the underfill layer formed vertically between the second semiconductor chips 120. In some embodiments, the underfill fillet 135c may surround side surfaces of at least one among the plurality of second semiconductor chips 120.

In addition, in some embodiments, as seen in FIG. 11D, the entire inner side surfaces of the dam structure 140 may contact the underfill fillet 135c. In addition, in some embodiments, the upper surface of the dam structure 140 may at least partially contact the underfill fillet 135c.

In some embodiments, curing of the underfill fillet 135c may be performed by applying light or heat.

When there is no dam structure 140, the underfill fillet 135 at the lowermost location between the first semiconductor chip 110 and the second semiconductor chip 120 may excessively flow outwardly, and cause product defects in the future. However, flowing of the underfill fillet 135 may be limited in the horizontal direction by the dam structure 140, and an excessive flowing may be prevented.

Referring to FIGS. 10 and 11E, side surface portions of the underfill fillet 135c may be partially removed by using a removal device 310 so that a thickness of an underfill fillet 135d does not exceed the first thickness T1 on the side surfaces of the plurality of second semiconductor chips 120 (S140).

The partial removal of the underfill fillet 135c may be performed by using various methods. For example, by performing a mechanical sawing process on the side surface portions of the underfill fillet 135c by using the removal device 310 as a blade, the partial removal on the underfill fillet 135c may be performed. In this case, a location of the removal device 310 may be determined so that a thickness of remaining portions of the underfill fillet 135d do not exceed the first thickness T1. The first thickness T1 has been described with reference to FIG. 3A, and descriptions thereof are omitted here. Alternatively, a laser sawing process may be used.

In some embodiments, a distance between the inner side surface 140s of the dam structure 140 and the plurality of second semiconductor chips 120 may be less than the first thickness T1. In this case, the recess pattern R as illustrated in FIG. 2 may be formed.

In some embodiments, the location of the removal device 310 may be determined so that the outside surface 135s of the remaining portion of the underfill fillet 135d, when extended, crosses the dam structure 140. In some embodiments, the removal device 310 may form the remaining portion of the underfill fillet 135d by sawing in the vertical direction (that is, in a Z direction) from an upper end of the underfill fillet 135c to the upper surface of the dam structure 140.

Referring to FIGS. 10 and 11F, the dam structure 140 may be removed (S150). When the dam structure 140 includes a polymer material such as a photoresist or a solder resist, silicon oxide, or silicon nitride, the dam structure 140 may be selectively removed by using an appropriate solution. However, in some embodiments, the dam structure 140 may not be removed but maintained.

Referring to FIGS. 10 and 11G, the molding layer 130 may be formed to surround the side surface of the top semiconductor chip 120T, and the top surface and the side surfaces of the underfill fillet 135d (S160).

The upper surface of the top semiconductor chip 120T (that is, the first upper surface 120Ta) may be exposed from the molding layer 130. In addition, the molding layer 130 may cover the entire upper surface and the entire side surfaces of the underfill fillet 135d. Accordingly, the underfill fillet 135d may not be exposed to the outside of the molding layer 130.

As described above, the first semiconductor chip 110 may include a portion of a semiconductor wafer, which has not been singulated yet. In this case, after the molding layer 130 is formed, the resulting structure may be separated into individual semiconductor packages by using a dicing process.

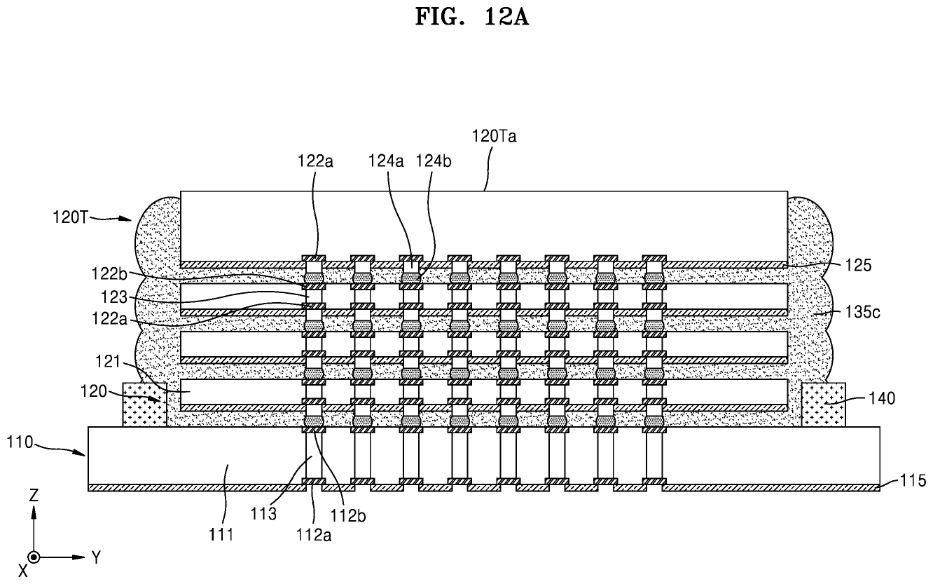

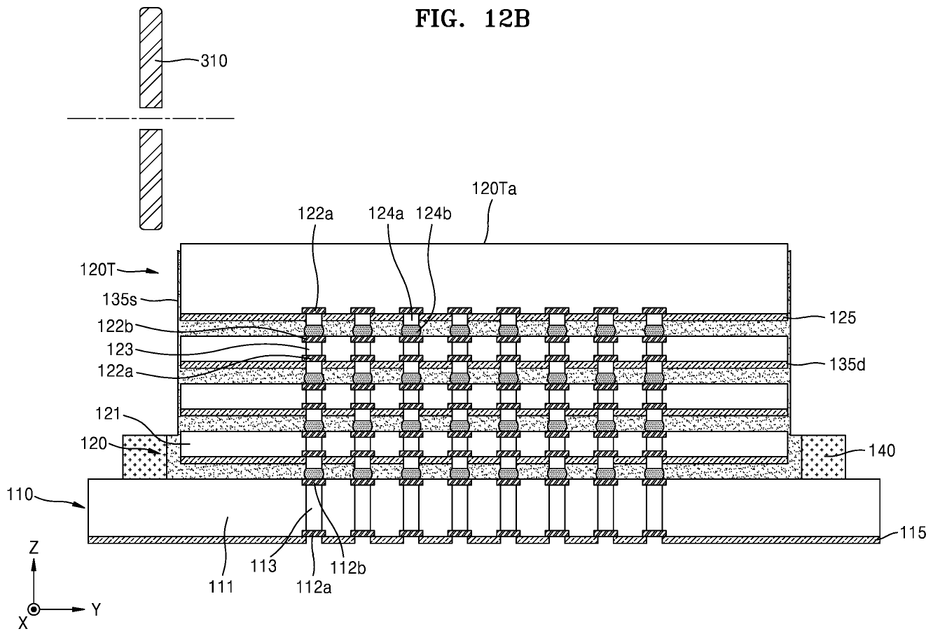

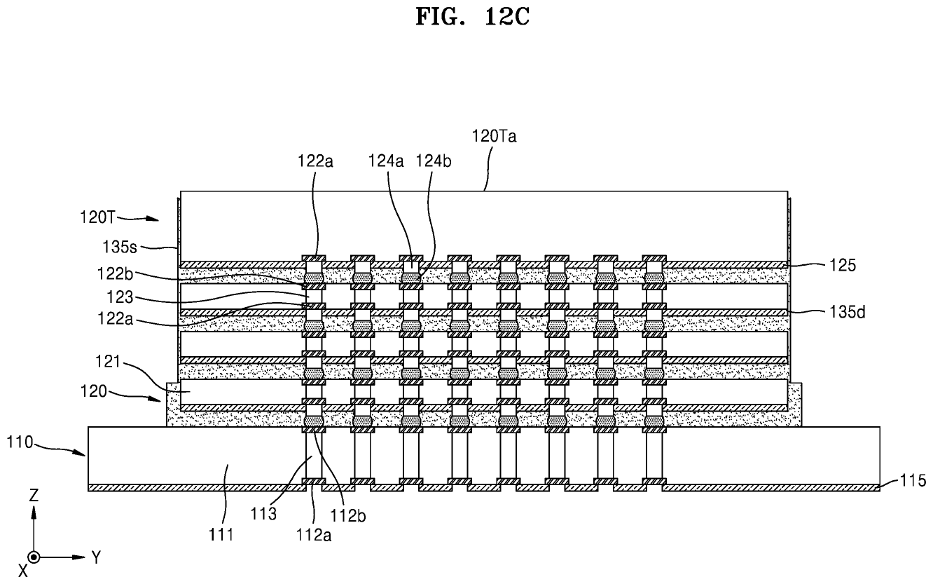

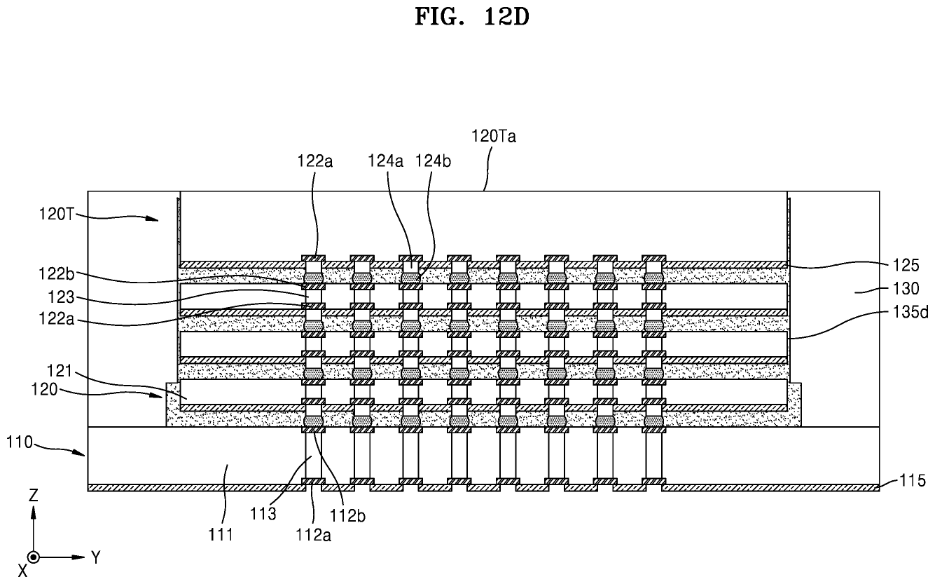

FIGS. 12A through 12D are side views illustrating a method of fabricating a semiconductor package, according to other example embodiments, and an operation illustrated in FIG. 12A may include an operation subsequent to the operation illustrated in FIG. 11C.

Referring to FIG. 12A, the plurality of second semiconductor chips 120 may be stacked on the first semiconductor chip 110, and a structure, in which the underfill fillet 135c protrudes in a lateral direction, may be obtained.

Referring to FIG. 12B, the side surface portions of the underfill fillet 135c may be partially removed by using the removal device 310. In this case, a location of the removal device 310 may be determined so that a distance between the inner side surface of the dam structure 140 and the plurality of second semiconductor chips 120 is greater than a distance between the side surfaces of the underfill fillet 135d and the plurality of second semiconductor chips 120. As a result, the underfill fillet 135d may include the protrusion pattern P (refer to FIG. 6) protruding in the lateral direction at a portion where the underfill fillet 135d meets the first semiconductor chip 110.

Referring to FIG. 12C, the dam structure 140 may be removed. When the dam structure 140 includes a polymer material such as a photoresist or a solder resist, silicon oxide, or silicon nitride, the dam structure 140 may be selectively removed by using an appropriate solution. However, in some embodiments, the dam structure 140 may not be removed but maintained.

Referring to FIG. 12D, the molding layer 130 may be formed to surround the side surfaces of the top semiconductor chip 120T, and the top surface and the side surfaces of the underfill fillet 135. Descriptions of this issue have been given in detail with reference to FIG. 11G, and detailed descriptions thereof are omitted here.

While the inventive concept has been particularly shown and described with reference to embodiments thereof, it will be understood that various changes in form and details may be made therein without departing from the spirit and scope of the following claims.

1. A semiconductor device comprising:
a plurality of semiconductor chips stacked on a substrate in a vertical direction;
a filler structure including a plurality of horizontal underfill layers formed between adjacent semiconductor chips of the plurality of semiconductor chips and between the substrate and the stack of semiconductor chips, and including underfill sidewalls formed around the horizontal underfill layers and the plurality of semiconductor chips; and
a molding resin surrounding the plurality of semiconductor chips at least on side surfaces of the semiconductor chips,
wherein the underfill sidewalls comprise a recess pattern, which is disposed on and along the side surfaces of at least one of the plurality of semiconductor chips, and is recessed in a direction parallel to an upper surface of the substrate at locations where the recess pattern meets the substrate.

2. The semiconductor device of claim 1,
wherein the recess pattern comprises a first surface facing the substrate and extending toward the plurality of semiconductor chips, and a second surface connecting the first surface to the upper surface of the substrate,
wherein the recess pattern extends along a periphery of a lowermost semiconductor chip among the plurality of semiconductor chips.

3. The semiconductor device of claim 2,
wherein a vertical distance between the first surface and the substrate is between about 20 μm and about 100 μm.

4. The semiconductor device of claim 2,
further comprising a dam structure provided on the substrate, the dam structure contacting the first surface and the second surface.

5. The semiconductor device of claim 4,
wherein the dam structure has four sides from a plan view, a width of one side is between about 200 μm and about 1200 μm in a direction in parallel to the upper surface of the substrate.

6. The semiconductor device of claim 4,
wherein an upper surface of the dam structure is on the same plane as the first surface.

7. The semiconductor device of claim 4,
wherein the dam structure comprises a metal, silicon oxide, silicon nitride, or a polymer.

8. The semiconductor device of claim 2,
wherein a vertical distance between the first surface and the substrate is about 0.5 times to about 1.8 times a vertical distance between an upper surface of the lowermost semiconductor chip among the plurality of semiconductor chips and the upper surface of the substrate.

9. The semiconductor device of claim 2,
wherein the underfill sidewalls comprise an outside surface contacting the molding resin, over the recess pattern, and
wherein the outside surface is substantially vertical with respect to the upper surface of the substrate.

10. The semiconductor device of claim 9,
wherein a horizontal distance between the outside surface and the side surfaces of the plurality of semiconductor chips is between about 40 μm and about 300 μm.

11. The semiconductor device of claim 2,
wherein the second surface is a flat surface.

12. A semiconductor package comprising:
a package substrate;
an interposer substrate stacked on the package substrate;
a first semiconductor device and a second semiconductor device arranged on the interposer substrate and spaced apart from each other in a lateral direction; and
a molding resin surrounding side surfaces of both the first semiconductor device and the second semiconductor device,
wherein the first semiconductor device comprises:
a buffer chip;
a plurality of memory devices stacked on the buffer chip and connected to each other via through-substrate vias (TSVs); and
an underfill fillet on side surfaces of the plurality of memory devices,
wherein the underfill fillet comprises a recess pattern, which is disposed on and along the side surfaces of at least one of the plurality of memory devices, and is recessed in a direction parallel to an upper surface of the buffer chip at locations where the recess pattern meets the buffer chip, and
wherein the recess pattern comprises: a first surface facing the buffer chip and extending toward the plurality of memory devices; and a second surface connecting the first surface to the upper surface of the buffer chip.

13. The semiconductor package of claim 12,
wherein the first surface is substantially parallel to the upper surface of the buffer chip.

14. The semiconductor package of claim 12,
wherein the second surface is substantially vertical with respect to the upper surface of the buffer chip.

15. The semiconductor package of claim 12,
wherein the recess pattern extends along a periphery of a lowermost memory device among the plurality of memory devices.

16. The semiconductor package of claim 15,
wherein a width of the first surface is between about 3 μm and about 40 μm.

17. The semiconductor package of claim 15,
further comprising a dam structure provided on the buffer chip and contacting the first surface and the second surface.

18. (canceled).

19. The semiconductor package of claim 12,
wherein a vertical distance between the first surface and the buffer chip is about 0.5 times to about 1.8 times a vertical distance between an upper surface of a lowermost memory device among the plurality of memory devices and the upper surface of the buffer chip.

20. The semiconductor package of claim 12, wherein the underfill fillet comprises underfill sidewalls formed around the first semiconductor device, and a plurality of horizontal underfill layers connected to the underfill fillet are formed between adjacent memory devices of the plurality of memory devices and between the buffer chip and the plurality of memory devices.

21. A semiconductor package comprising:
a package substrate;
an interposer substrate stacked on the package substrate;
a first semiconductor device and a second semiconductor device arranged on the interposer substrate to be spaced apart from each other in a lateral direction; and
a molding resin surrounding side surfaces of both the first semiconductor device and the second semiconductor device,
wherein the first semiconductor device comprises:
a buffer chip;
a plurality of memory devices stacked on the buffer chip and connected to each other via through-substrate vias (TSVs); and
underfill sidewalls on side surfaces of the plurality of memory devices,
wherein the underfill sidewalls comprise an underfill fillet that includes a protrusion pattern, which is disposed on and along the side surfaces of the plurality of memory devices and protrudes in a direction parallel to an upper surface of the buffer chip at locations where the protrusion pattern meets the buffer chip,
wherein the protrusion pattern comprises a first surface which is parallel to the buffer chip and extends in a direction away from the plurality of memory devices, and a second surface connecting the first surface to the upper surface of the buffer chip and comprising a flat surface substantially vertical with respect to the upper surface of the buffer chip.

22-26. (canceled).
